(19) United States
(12) Patent Application Publication
(10) Pub. No.: US 2025/0191919 A1
(43) Pub. Date: Jun. 12, 2025

(54) High-Temperature Material Processing In The Absence Of Hydrogen

(71) Applicant: The Government of the United States of America, as represented by the Secretary of the Navy, Arlington, VA (US)

(72) Inventors: Alan G. Jacobs, Rockville, MD (US); Boris N. Feigelson, Springfield, VA (US)

(73) Assignee: The Government of the United States of America, as represented by the Secretary of the Navy, Arlington, VA (US)

(21) Appl. No.: 18/530,442

(22) Filed: Dec. 6, 2023

(51) Int. Cl. H01L 21/225

(52) U.S. Cl. CPC H01L 21/2258

(57) ABSTRACT

Methods of preventing hydrogen penetration into a material during high-temperature processing such as annealing of an ion-implanted GaN sample. In some embodiments, a hydrogen getter that can withstand the high temperatures is used, where the getter includes a getter material which can capture hydrogen from the annealing ambient before it can diffuse into the material, a surface layer to prevent damage to the getter from exposure to nitrogen in the annealing ambient and further includes an intermediate barrier layer to prevent mixing of the getter material and a surface layer in order to protect the getter during the high-temperature processing. In other embodiments, a hydrogen-blocking layer situated adjacent to the material being processed is used, where the hydrogen-blocking layer prevents hydrogen from the ambient from penetrating into the material.

### CROSS-REFERENCE

This application is a Nonprovisional of and claims the benefit of priority under 35 U.S.C. § 119 based on U.S. Provisional Patent Application No. 63/386,705 filed on Dec. 9, 2022. The Provisional application and all references cited herein are hereby incorporated by reference into the present disclosure in their entirety.

### FEDERALLY-SPONSORED RESEARCH AND DEVELOPMENT

The United States Government has ownership rights in this invention. Licensing inquiries may be directed to Office of Technology Transfer, US Naval Research Laboratory, Code 1004, Washington, DC 20375, USA; +1.202.767.7230; techtran@nrl.navy.mil, referencing Navy Case #211360.

### TECHNICAL FIELD

The present invention relates to the annealing of gallium nitride (GaN) to activate ion-implanted dopants in the absence of hydrogen to reduce diffusion of the dopant ions and prevent their migration into the GaN.

### BACKGROUND

Ion-implanted dopant activation is a key enabling technique for high voltage, high power, and high frequency gallium nitride (GaN) electronics. Annealing is necessary after implantation of the dopant ions to remove damage to the material's lattice from the implantation process and to activate the dopants by moving the dopant atoms onto the GaN lattice at specified locations within the lattice.

However, GaN is metastable at high temperatures and atmospheric pressure, i.e., it decomposes into metallic gallium and nitrogen gas at the high temperatures needed for annealing. Consequently, when annealing GaN at high temperatures, higher than atmospheric pressure nitrogen is often used to stabilize its solid phase and preclude or reduce its decomposition. See Jacobs, A. G., Spencer, J. A., Hite, J. K., Hobart, K. D., Anderson, T. J. and Feigelson, B. N. (2023), Novel Codoping Moiety to Achieve Enhanced P-Type Doping in GaN by Ion Implantation. Phys. Status Solidi A, 220:2200848; Jacobs, A. G., Feigelson, B. N., Hite, J. K., Gorsak, C. A., Luna, L. E., Anderson, T. J. and Kub, F. J. (2020), Role of Capping Material and GaN Polarity on Mg Ion Implantation Activation. Phys. Status Solidi A, 217:1900789; see also Sierakowski, K.; Jakiela, R.: Lucznik, B.; Kwiatkowski, P.; Iwinska, M.; Turek, M.; Sakurai, H.; Kachi, T.; Bockowski, M. High Pressure Processing of Ion Implanted GaN. Electronics 2020, 9, 1380; Hideki Sakurai et al 2020 “Redistribution of Mg and H atoms in Mg-implanted GaN through ultra-high-pressure annealing,” Appl. Phys. Express 13 086501; and Hideki Sakurai, Masato Omori, Shinji Yamada, Yukihiro Furukawa, Hideo Suzuki, Tetsuo Narita, Keita Kataoka, Masahiro Horita, Michal Bockowski, Jun Suda, Tetsu Kachi; Highly effective activation of Mg-implanted p-type GaN by ultra-high-pressure annealing. Appl. Phys. Lett. 30 Sep. 2019; 115 (14): 142104.

During such a high pressure anneal, often occurring at 10-2000 MPa in pressure, the GaN is heated at high pressure in a nitrogen ambient. However, this ambient can have minor contamination with oxygen, water, hydrogen, and other gasses, and during an activation anneal, often occurring from 1200-1500° C. for a duration ranging from minutes to hours, hydrogen in the ambient gas can diffuse into the GaN. This diffused hydrogen can drastically affect the diffusivity of dopant species, as illustrated by the plots in FIGS. 1 and 2. For example, during activation of implanted magnesium to produce p-type GaN, the magnesium may diffuse multiple microns into the GaN material after implantation only a few hundred nanometers deep.

The plot in FIG. 1 shows diffusion of magnesium many microns in depth after a short duration anneal in a typical-purity nitrogen environment, as published in Sierakowski et al, supra.

Similarly, the plot in FIG. 2A shows that by using an ultra-high purity nitrogen ambient at high pressure, implanted dopants can be caused to quickly diffuse to 2 microns in depth from an initial 500 nm implant.

Significant diffusion of such dopants proves deleterious as this makes control of the final structure difficult, since the diffused dopant atoms can move outside of the locations within the material specified by a desired doping profile. Shallow junctions between p-type and n-type material can also be moved due to this diffusion, and high dopant concentrations spread out, precluding some device designs. In addition, high surface concentrations of the implanted dopants can greatly enhance ohmic contact formation in the final devices; because ohmic contact formation is a necessary step in eventual device fabrication for many architectures, diffusion of the dopants into the bulk of the GaN material must be controlled to enable fabrication of high-quality electronic devices.

Furthermore, hydrogen passivates p-type doping by magnesium (both incorporated by growth or implant) such that it must be removed before the doped material will produce free holes for device operation. Diffusion of hydrogen and magnesium deep into the GaN then produces additional difficulty as the deeper the hydrogen diffuses, the more difficult it is to remove for device fabrication.

One potential solution to this problem is to remove the hydrogen from the initial anneal ambient.

However, this is difficult for several reasons.

First, hydrogen is present in the feed gasses and is concentrated in the gasses at the temperatures and pressures used for annealing of GaN. As the anneal ambient pressure increases, any minor component of the source gas is also pressurized. For example, a 1 part-per-million concentration of hydrogen in nitrogen (a common concentration in ultra-high purity nitrogen feed gases) at 1000 MPa anneal ambient will have a 1 kPa vapor pressure in the chamber or ˜1% of atmospheric pressure. This vapor pressure of hydrogen is significant and introduces a large source of hydrogen that can diffuse into the GaN and thus produces a large volume of hydrogen that must be removed. Often, the purest nitrogen sources are filtered/purified at the point of use to ˜1 ppb level, but this still leaves of order 1 Pa of hydrogen vapor pressure which still acts as a hydrogen source.

Second, hydrogen is often generated in the anneal chamber. Any water present in the chamber or anneal ambient gas will react with the heating elements. Often these heating elements are made of carbon or metals which react with the water at high temperature to steal the oxygen and produce free hydrogen. This means that even if the feed gas is perfectly pure, any water adsorbed to the walls of the anneal chamber will produce hydrogen in-situ. This is often unavoidable.

Third, additional sources of hydrogen can include outgassing from the steel pressure vessel, sealing materials or gaskets, and other leaks from the outside world into the high pressure chamber during the loading or operating processes.

Thus, there needs to be a way to prevent hydrogen from interacting the GaN during annealing.

### SUMMARY

This summary is intended to introduce, in simplified form, a selection of concepts that are further described in the Detailed Description. This summary is not intended to identify key or essential features of the claimed subject matter, nor is it intended to be used as an aid in determining the scope of the claimed subject matter. Instead, it is merely presented as a brief overview of the subject matter described and claimed herein.

The present invention provides a hydrogen getter that can withstand high-temperature processing such as that used to anneal an ion-implanted GaN sample.

A getter in accordance with the present invention includes a getter material such as titanium or yttrium which can capture hydrogen from the annealing ambient before it can diffuse into the material being annealed and cause excessive dopant diffusion or passivation of doping species, with a palladium or platinum surface layer to prevent damage to the getter from exposure to nitrogen in the annealing ambient, an intermediate diffusion-blocking layer of chromium, platinum, molybdenum, tungsten, or other suitable material, and optionally can include an intermediate diffusion-blocking layer to prevent mixing of the getter material and the surface layer. The layered structure of a getter in accordance with the present invention protects the getter from the high process temperatures needed for heat treatment of materials such as GaN.

The present invention also provides methods of preventing hydrogen penetration into a material during high-temperature processing.

In one embodiment of a method for preventing hydrogen penetration into a material during high-temperature processing in accordance with the present invention, a high-temperature tolerant hydrogen getter is placed within the annealing chamber, either as a separate material situated nearby the sample or as a cap layer placed on top of or in intimate contact with the sample to be annealed.

In another embodiment of a method for preventing hydrogen penetration into a material during high-temperature processing in accordance with the present invention, a layer of a hydrogen-impermeable material such as n-type gallium nitride is placed on an upper surface or within the material to be annealed.

In another embodiment of a method for preventing hydrogen penetration into a material during high-temperature processing in accordance with the present invention, a layer of hydrogen-impermeable material is produced in the bulk material being processed in-situ by means of implantation of donors, such as silicon, oxygen, germanium, etc. This implanted hydrogen-impermeable layer can extend everywhere across the surface of the bulk material being processed or can be selectively patterned to only protect some regions.

The methods and structures in accordance with the present invention can prevent the penetration of hydrogen into a material sample being processed at temperatures between about 500 and 2000° C. and at pressures from about 0.1 MPa to about 2000 MPa.

### BRIEF DESCRIPTION OF THE DRAWINGS

FIG. 1 is a plot illustrating how dopant atoms can rapidly diffuse from the surface of a GaN sample into the bulk as the implanted sample is heated to annealing temperatures with a standard high pressure nitrogen atmosphere as a function of the anneal temperature.

FIGS. 2A and 2B are plots illustrating diffusion of magnesium (Mg) dopant atoms into a GaN sample when the sample is annealed for 30 minutes at 1300° C. under ultra-high purity nitrogen gas at 380 MPa without (FIG. 2A) and with (FIG. 2B) a hydrogen getter to reduce the presence of hydrogen in the annealing chamber.

FIG. 3 is a block diagram illustrating use of a hydrogen getter that removes hydrogen from the ambient atmosphere during annealing of a Mg-implanted GaN sample.

FIGS. 4A-4C are photographic images illustrating aspects of the performance of a conventional titanium or palladium-coated titanium getter, where FIG. 4A illustrates a conventional “high-temperature” titanium (Ti) getter before annealing and having a temperature rating of 500° C., FIG. 4B illustrates the conversion of such a conventional Ti getter to TiN after being subjected to a temperature of 1300° C. for 60 minutes in a nitrogen atmosphere, and FIG. 4C illustrates the condition of a conventional Ti getter with an additional palladium (Pd) layer (Ti/Pd getter) after such heating.

FIGS. 5A and 5B are block schematics illustrating the structure of exemplary hydrogen getters in accordance with the present invention.

FIGS. 6A-6C are photographic images illustrating the condition of a conventional Ti/Pd getter film (FIG. 6A) after one hour at 1300° C. as compared to the Ti/Pt/Pd (FIG. 6B) and Ti/Cr/Pt/Pd (FIG. 6C) getter films in accordance with the present invention.

FIGS. 7A and 7B are photographic images illustrating the condition of an exemplary Y/Cr/Pt/Pd getter film before (FIG. 7A) and after one hour at 1300° C. (FIG. 7B).

FIGS. 8A-8D are block schematics illustrating use of a getter layer (FIGS. 8A and 8B), a hydrogen-impermeable cap (FIG. 8C), or in-situ generated hydrogen-impermeable barrier (FIG. 8D) to prevent diffusion of hydrogen into a GaN sample during annealing in accordance with additional aspects of the present invention.**

FIGS. 9A and 9B are plots illustrating the effects of including a hydrogen getter in accordance with this invention during an anneal of GaN at 1300° C. for 30 minutes, where FIG. 9A shows as implanted, no hydrogen is inside the GaN, after annealing without getter, the hydrogen diffuses into the GaN, after annealing with the getter, the hydrogen concentration is reduced.

FIG. 9B shows the magnesium concentration in the same region showing a reduction in the magnesium diffusion into the GaN by ˜35% at 1 micron in depth with the use of the hydrogen getter.

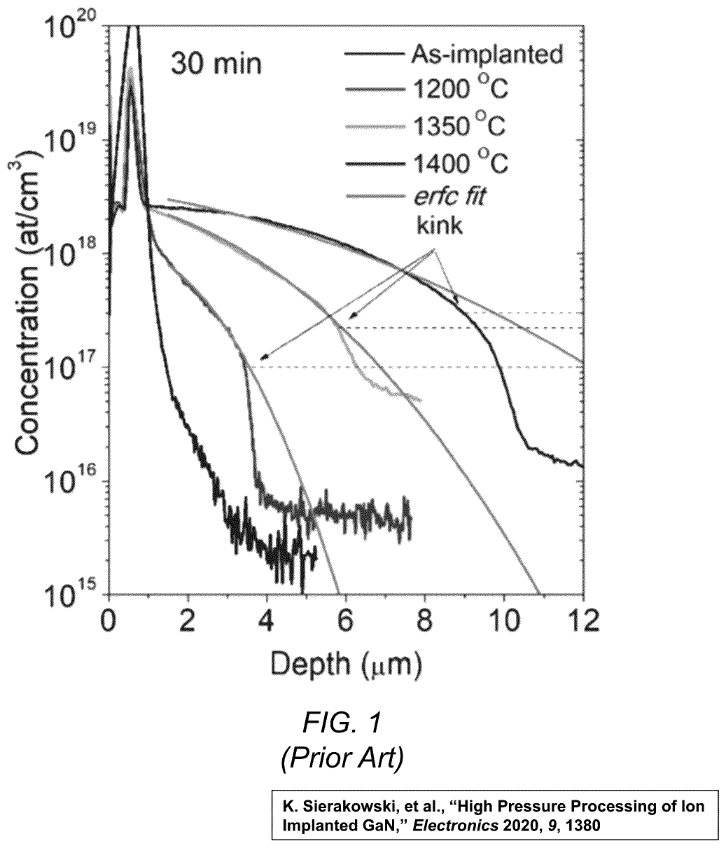

### DETAILED DESCRIPTION

The aspects and features of the present invention summarized above can be embodied in various forms. The following description shows, by way of illustration, combinations and configurations in which the aspects and features can be put into practice. It is understood that the described aspects, features, and/or embodiments are merely examples, and that one skilled in the art may utilize other aspects, features, and/or embodiments or make structural and functional modifications without departing from the scope of the present disclosure.

For example, although the present invention is described in the context of a getter used to prevent penetration of hydrogen in connection with annealing ion-implanted GaN, the principles of the present invention can be used in connection with annealing or other high-temperature processing of other III-Nitride materials such as AlN, InN, ScN, BN and alloys thereof with or without GaN, or in connection with high-temperature heat treatment of any other suitable material such as tantalum, iron, steel, titanium, cobalt, vanadium, nickel, zirconium, copper, aluminum, and their alloys, or in connection with high-temperature operation of any other suitable devices such as vacuum tubes, semiconductor manufacturing, or nuclear fusion reactors. The methods and devices in accordance with the present invention can prevent the penetration of hydrogen into a material sample being processed at temperatures between about 500 and 2000° C. and at pressures from about 0.1 MPa to about 2000 MPa.

An described above, GaN can be implanted with dopant ions in accordance with a predefined doping profile to produce areas within the GaN bulk having a desired p- or n-type conductivity. To ensure that the implanted dopants are located at the proper places within the GaN material to achieve such conductivity, the implanted GaN is annealed to repair damage to the crystal structure caused by the ion implantation and to cause the implanted ions to move to the desired locations within the crystal lattice. If p-type doping is desired, the GaN can be implanted with ions of Mg or others, while if n-type doping is desired ions of silicon, oxygen, germanium, tin, or others can be implanted. In both cases, the ion-implanted GaN is annealed at high temperatures, typically from 1200-1500° C., for a total duration ranging from minutes to hours. However, as noted above, conventional getters cannot withstand these high temperatures and other annealing conditions needed to activate dopants in GaN.

The present invention solves this problem by providing a hydrogen getter and hydrogen-blocking layer that can withstand the high temperatures and other annealing conditions required to anneal an ion-implanted GaN sample.

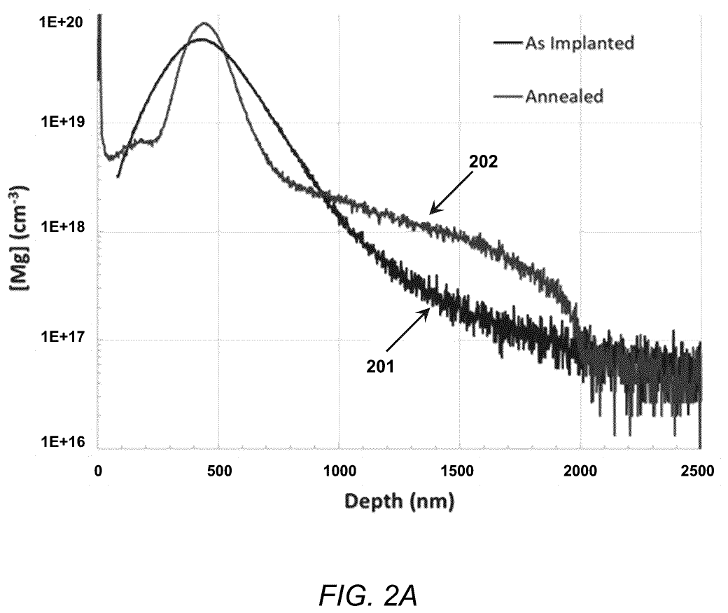

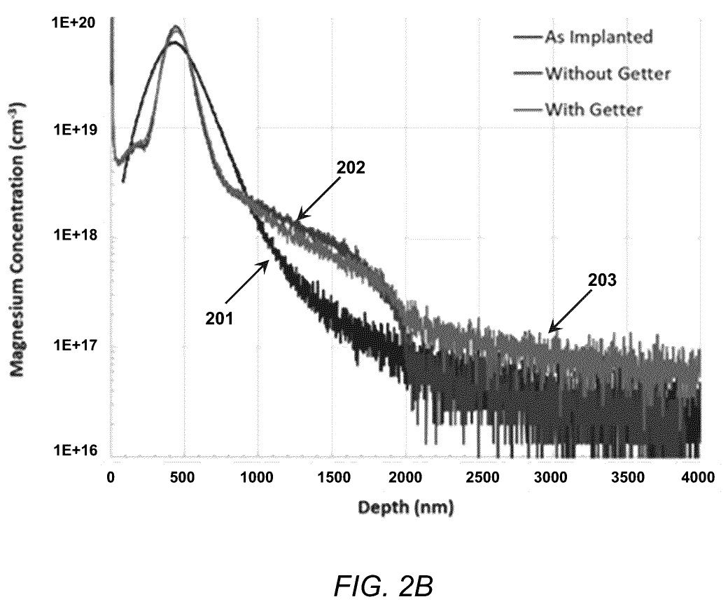

FIG. 2A shows the effect of annealing under high pressure on the magnesium profile within GaN as measured by secondary ion mass spectrometry (SIMS), where an initially broad profile from a single energy implant (201) shows significant motion after annealing (202). After annealing, some magnesium diffuses to the surface of the GaN and is lost, some localizes near the location of maximum implant damage, e.g., at about 450 nm in this case, and further some diffuses deeply into the GaN material as exhibited by the excess of magnesium concentration beyond approximately 1000 nm after annealing.

FIG. 2B shows the magnesium density profiles in FIG. 2A along with a profile of a sample annealed with a getter (203) exhibiting a lower concentration of magnesium than annealing without a getter (202) at the same conditions at depths greater than 1000 nm. Beyond 2000 nm at these conditions, the magnesium concentration follows the as-implanted profile (201) for both conditions. The small increase shown for the sample annealed with a getter (203) is due to an increase in the SIMS noise floor and not indicative of the magnesium concentration, only the limitation on that particular measurement run.

As used herein, the term “getter” refers to a material which adsorbs, absorbs, or bonds to a target gas and removes it from the ambient conditions. Commonly this may consist of a reactive metal which is exposed to the ambient during operation to remove the target gas. The getter must be carefully chosen for (1) its ability to survive the process conditions, (2) its capacity to absorb the target gas, and (3) its capability to maintain the target vapor pressure at all process temperatures.

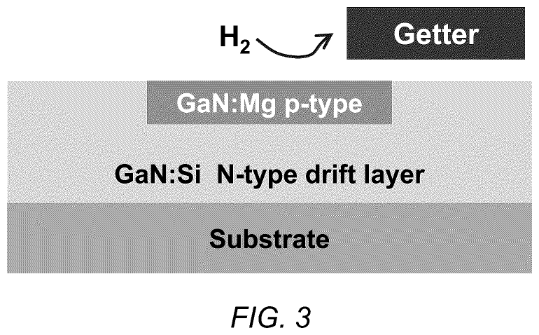

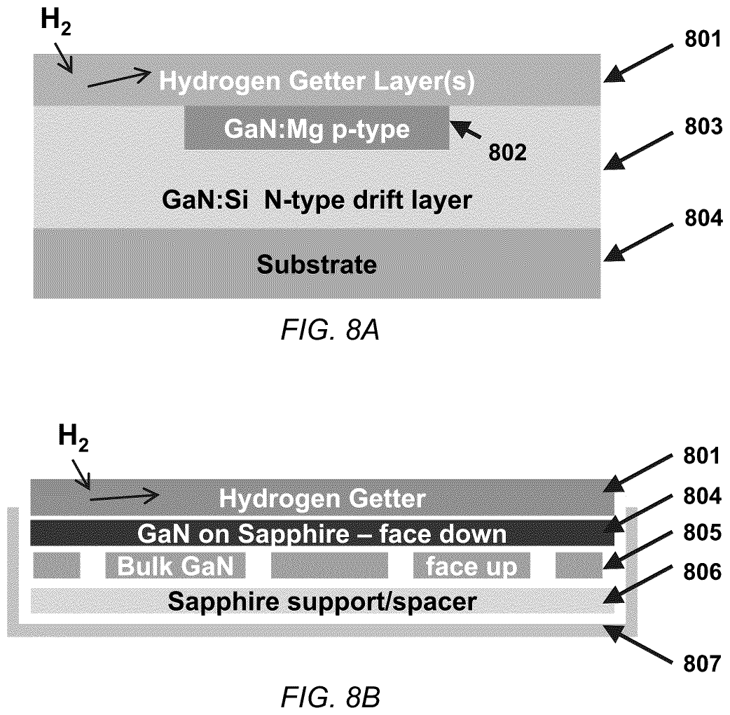

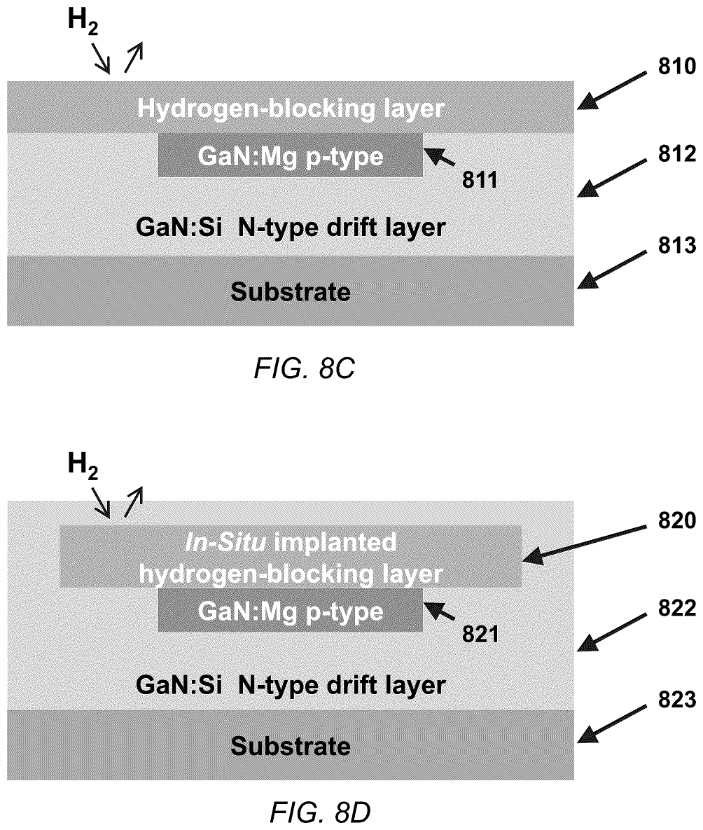

Such a getter can be located anywhere within the reaction chamber, so long as it is in a position to absorb the hydrogen from the annealing ambient and/or block the hydrogen before it can diffuse into the material during annealing. For example, in many embodiments, such as the one as illustrated by the block schematic in FIG. 3, the getter can be separate from the GaN material to be annealed, while in other embodiments, such as in the embodiment illustrated in FIG. 8A discussed below, the getter can be applied as a cap to the GaN material.

Reactive metals such as titanium are particularly effective at removing hydrogen. However, titanium has multiple drawbacks which can impair its usefulness as a getter. For example, titanium reacts with gasses in the annealing ambient, forming oxides and nitrides which produce a barrier to absorption of hydrogen in the bulk of the titanium. Additionally, both titanium oxide and titanium nitride have much lower ability to absorb hydrogen than titanium metal. In particular, at the high pressures and temperatures needed to anneal GaN, i.e., elevated pressures of nitrogen at 1200-1500° C., titanium readily reacts with nitrogen in the annealing ambient to form titanium nitride, potentially transforming the entire getter material into a material that can absorb only a small amount of hydrogen and releasing any previously absorbed hydrogen back into the annealing atmosphere.

Previously, the effect of this surface oxide/nitride formation has been countered by applying a palladium surface coating to a titanium getter material to form a Ti/Pd getter, where the Pd coating prevents surface oxidation or nitridation while retaining the getter's hydrogen absorption capability. See, e.g., U.S. Pat. No. 6,822,880 to Kovacs et al., entitled “Multilayer Thin Film Hydrogen Getter And Internal Signal Emi Shield For Complex Three-Dimensional Electronic Package Components.” However, although both titanium and palladium have melting points above the process temperature (approximately 1668° C. and 1555° C., respectively), such a Ti/Pd getter will not survive the high annealing temperatures needed for processing ion-implanted GaN for two reasons.

First, at these temperatures, palladium will readily diffuse and mix with the titanium, reducing its ability to protect the titanium from nitridation during annealing. Second, the binary compounds formed as a result of this mixing have a minimum liquidus temperature (˜1120° C.) below the minimum process temperature, meaning the interface melts rapidly at the process temperatures, further degrading any performance before bulk diffusion dominates.

In addition, because of the diffusion of nitrogen from the ambient into the Pd/Ti stack, TiN is formed within the Pd layer, which provides fast diffusion pathways through the Pd enabling rapid consumption of the getter and formation of TiN.

Thus, in practice, a Ti/Pd getter fails to work at high annealing temperatures.

Additionally, for any un-reacted getter, the hydrogen sorption capacity of the metal decreasing with increasing temperature. As an example, the sorption capacity of titanium, i.e. the number of hydrogen atoms the metal can absorb per gram of metal, is approximately 100× lower at 1000° C. than at 500° C. with further diminishing capacity at the process temperature. An alternative base getter material, yttrium, has much higher sorption capacity at these high annealing temperatures, however, yttrium also suffers from degradation and formation of nitrides, specifically YN.

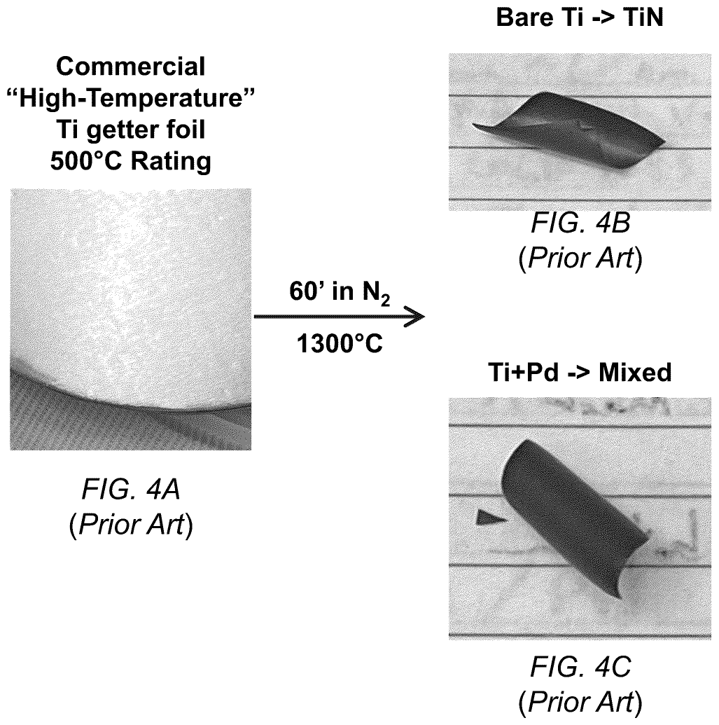

The photographic images in FIGS. 4A-4C illustrate these drawbacks of both titanium getters and palladium-coated titanium getters. As shown in FIG. 4A, a commercially available “high-temperature” titanium (Ti) getter foil rated at being able to withstand temperatures of 500° C. was subjected to temperatures of 1300° C. for 60 minutes in an atmospheric pressure nitrogen ambient, i.e., to less aggressive than typical GaN annealing conditions. As indicated in FIG. 4B, a bare Ti foil reacts with nitrogen in the ambient to form TiN which, as described above, is not effective to remove hydrogen from the atmosphere. As illustrated by the image shown in FIG. 4C, coating the Ti film with a layer of palladium, as is done in the current state of the art, does not prevent failure of the Ti getter under these conditions since, as noted above, such a Pd-coated Ti film experiences mixing of the Pd and Ti at the interface between the two metals, resulting in greatly diminished functional capacity to absorb ambient hydrogen.

Thus, currently commercially available getters cannot survive the process temperatures and timescales needed to anneal GaN and activate dopants without the deleterious effects of hydrogen in the ambient.

A getter construct sufficient to function during these harsh conditions must (1) utilize a bulk getter material to absorb the hydrogen, such as titanium or yttrium, (2) incorporate a surface protective layer to preclude oxygen or nitrogen attack while simultaneously remaining conducive to hydrogen diffusion, such as palladium or platinum, and (3) incorporate diffusion-blocking films between the bulk getter material and the surface film to reduce diffusion and mixing such that both the surface and bulk retain their respective functions for the process duration.

The present invention provides such a getter.

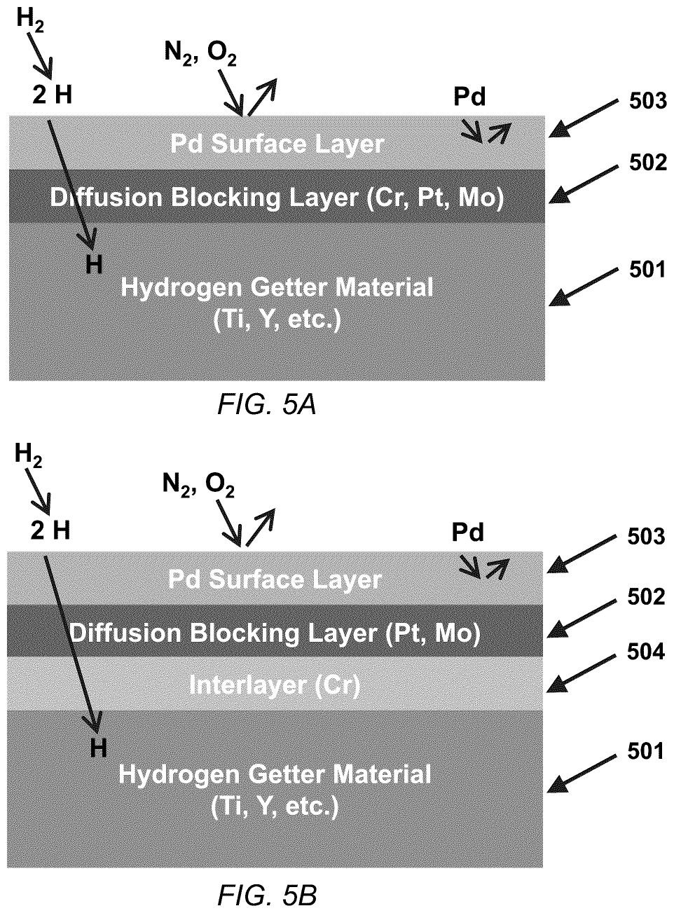

The block schematics in FIGS. 5A and 5B illustrate two exemplary embodiments of a getter in accordance with the present invention. Such a getter may incorporate a getter material, typically a reactive refractory material such as titanium (Ti), yttrium (Y), etc., or an alloy thereof, which can withstand the high temperatures required for GaN annealing while simultaneously absorbing and retaining hydrogen, a surface layer of palladium (Pd), platinum (Pt) or an alloy thereof, and one or more intermediate diffusion-blocking layers disposed between the getter material and the surface layer. The diffusion-blocking films could be any material, such as metals, carbides, nitrides, oxides, etc., which sufficiently retard mixing while remaining transmissible to the hydrogen for the getter to function. Exemplary diffusion-blocking materials that may be used in a high-temperature getter in accordance with the present invention are chromium (Cr), platinum (Pt), nickel (Ni), tantalum (Ta), Molybdenum (Mo), Tungsten (W) etc., and alloys thereof, but any other suitable materials can also be used.

It should be noted that platinum has been listed as both a potential diffusion-blocking layer and a potential surface layer. Although platinum has a very high melting point, it has a liquidus with titanium at approximately 1310° C. such that it cannot be used directly in contact with titanium getters above this temperature, its use as part of a multi-layer diffusion-blocking layer can be envisioned. It can also be selected as a potential surface layer for instances where palladium, with a melting point of ˜1550° C. is insufficient, while platinum, with a melting point of ˜1770° C., is better suited. One skilled in the art will readily recognize that getters optimized to the lower annealing temperature range will differ from those suitable for a higher temperature range.

Thus, in one exemplary embodiment such as that illustrated in FIG. 5A, a getter in accordance with the present invention includes a bulk getter material 501, e.g., Ti, Y, etc. which can absorb hydrogen from the ambient atmosphere along with a surface layer 503 of Pd, Pt, or other suitable material as in conventional hydrogen getters currently available, but also includes an intervening diffusion-blocking layer 502 such as a layer of Cr, Pt, Mo, etc. added between the Ti getter material layer 501 and the Pd surface layer 503 to form, e.g., a Ti/Pt/Pd stack. Both Pt and Pd remain insoluble up to 770° C., while at higher temperatures have no reduction in melting point below that of palladium itself, which is about 1550° C. Furthermore, all binary mixtures of Pt and Ti remain solid to at least 1310° C.

As shown in FIG. 5A, hydrogen (H₂) goes from the gas ambient into Pd surface layer 503, through diffusion-blocking layer 502, and into getter material 501 while ambient gasses that are not desired to be absorbed, such as nitrogen (N₂) and oxygen (O₂), do not react with the surface Pd layer. Simultaneously, the Pd surface layer does not penetrate the diffusion-blocking layer to mix with the getter material. At these temperatures, some finite mixing or diffusion of the getter, diffusion-blocking, and surface layers may be present, but so long as the material remains solid without melting, the layers will function for a finite time, depending upon their thicknesses and the anneal temperature. However, if a liquid phase is formed, rapid mixing of the materials occurs in the liquid, with the surface morphology of the film often being negatively affected from formation of droplets such that the film will no longer protect the bulk getter material, which may quickly fail. For example, a Pt diffusion-blocking layer on a Ti getter is ill-advised for annealing at temperatures beyond 1300° C. since platinum and titanium have a minimum liquidus temperature of ˜1320° C., and going above this temperature would produce a liquid phase and loss of the diffusion-blocking layer's protection to the bulk titanium getter volume. Consequently, avoiding liquid phases is highly desirable.

Thus, in other embodiments, such as that shown by the block schematic in FIG. 5B, further improvement can be gained by introducing an additional interlayer such as chromium interlayer 504 between the diffusion-blocking layer 502 and getter material layer 501 to provide additional protection to the getter material. An exemplary getter in accordance with this embodiment of the present invention would comprise a Ti/Cr/Pt/Pd stack of titanium getter material 501, chromium interlayer 504, platinum diffusion-blocking layer 503, and palladium surface layer 503. The addition of chromium to this stack is beneficial, as the liquidus minimum between chromium and titanium is ˜1410° C. and between platinum and chromium is ˜1500° C., such that there is no intermixing of the two materials due to melting at the interfaces until >1400° C., improved from ˜1300° C. without the chromium interlayer. Interlayer 504 can be any suitable material so long as its maximum liquidus temperature or diffusion-blocking characteristics are improved from the material stack without the interlayer.

In other embodiments, because chromium and palladium have a minimum liquidus of ˜1310° C., there will be little or no intermixing of the two materials at their interface, and so chromium may be used as the diffusion-blocking layer 502 rather than platinum, without the need for an interlayer between the diffusion-blocking layer and the getter material.

The interlayer and/or diffusion-blocking layers can be deposited on the surface of the getter material by any suitable means including but not limited to electroplating, physical vapor deposition (such as electron beam or thermal evaporation, sputtering, pulsed laser deposition), chemical vapor deposition, atomic layer deposition, or other suitable means.

The thicknesses of the various layers in a high-temperature getter in accordance with the present invention can range from 10 nm to 100 microns in thickness though generally much less than the getter material itself and often of order 50-5000 nm thick. The getter material may be any thickness suitable and necessary and sized for the absorption capacity needed in the specific application. Often this may be as little as 10 to 100 microns but is dependent upon the required absorption capacity. More surface area of getter can also absorb hydrogen more quickly and effectively such that more area of a thinner getter may prove sufficient instead of a smaller surface area of a thicker material. The getter can be in a bulk form or in powder form. In case of a powder, the smaller particle size and commensurately greater surface area, the more rapid and efficient the sorption for a given mass of getter material.

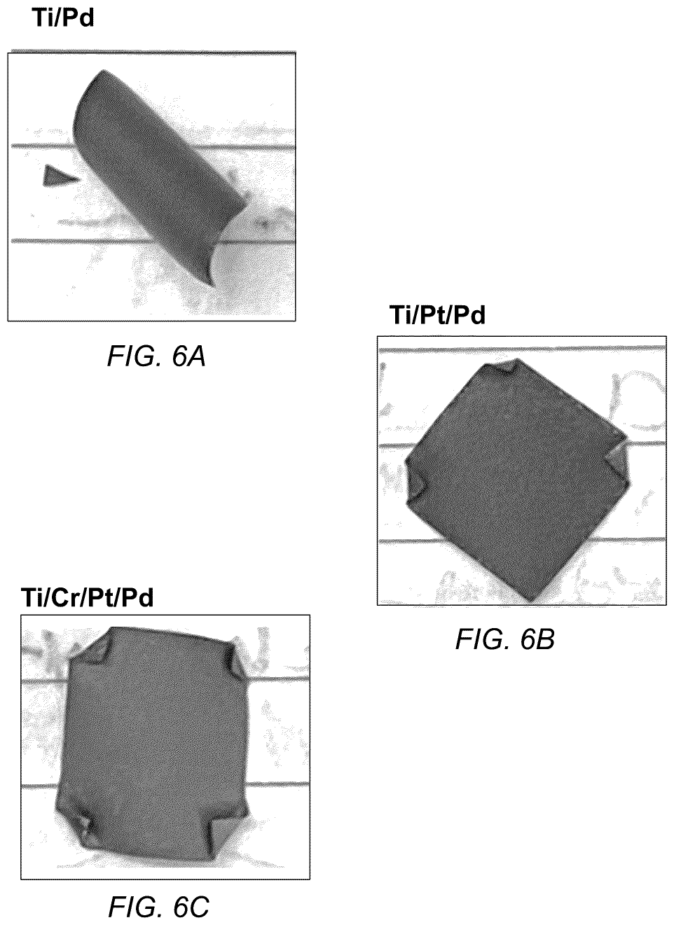

The photographic images in FIGS. 6A-6C illustrate the advantageous performance of the introduction of the platinum and chromium interlayers into the getter stack in accordance with the present invention. The image in FIG. 6A shows failure of a commercial Ti/Pd getter after 60 minutes of exposure to atmospheric pressure nitrogen at 1300° C. as evidenced by the physical deformation and brown discoloration. The image in FIG. 6B shows that inclusion of a platinum diffusion-blocking layer is sufficient to reduce mixing to the point that deformation is prevented and discoloration is less, to a blue hue. Finally, the image in FIG. 6C shows that a multilayer stack with Cr/Pt/Pd added to the Ti getter prevents deformation and further reduces discoloration such that a significant area of the getter retains a silvery metal appearance as evidence of greatly reduced mixing and nitridation.

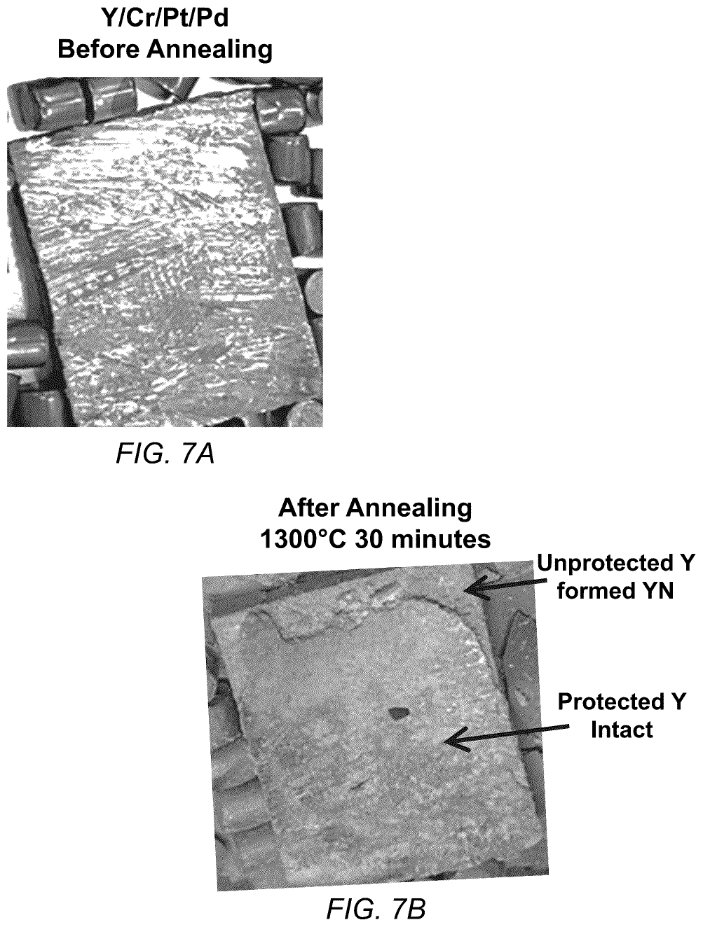

A stack structure having platinum and chromium interlayers such as described above with respect to a titanium getter can also be used to protect a palladium-capped yttrium getter. The photographic image in FIG. 7A shows a bulk piece of yttrium before annealing at 1300° C. for 30 minutes under 3.8 kbar pressure of nitrogen. As shown by the image in FIG. 7B, after annealing, the corners and edges of the structure which were unprotected from the anneal gas have formed YN powder while the regions protected by the Cr/Pt/Pd stack show an intact surface.

The high-temperature getter materials used in accordance with the present invention are difficult to design and select from a materials standpoint due to the aggressive conditions involved, which are simultaneously at very high pressure and above the melting point of most solids. In addition, the complex interactions of the multiple materials used in a getter in accordance with the present invention makes their design and fabrication even more difficult. In order to design such getters, those skilled in the art must take into account ternary, quaternary, or qintinary phase diagrams wherein significant entropic effects greatly distort estimations from knowledge of binary phase diagrams. Additionally, current state of the art focuses on lower temperatures due to the greatly reduced sorption capacity of such getters (Ti) at these extreme conditions. All of these aspects make the getters of the present invention beyond what has been attained with the current state of the art.

In other aspects, the present invention also provides methods for high-temperature processing of materials, e.g., the annealing of dopant-implanted GaN, without permitting the diffusion of hydrogen from the processing ambient into the material being processed.

As described above, in order to activate ion-implanted dopants in a material such as GaN, implantation damage to the material's crystal lattice must be remedied and the implanted ions must be moved from the random positions in which they were implanted onto the proper lattice sites necessary to achieve a desired doping profile. Remedying the implantation damage and moving the implanted ions requires annealing at high temperatures relative to the material's melting point. In the case of GaN, this requires temperatures of approximately 1200-1500° C., temperatures at which the material requires high nitrogen pressures to remain stable. See U.S. Pat. No. 8,518,808 to Feigelson et al., “Defects Annealing and Impurities Activation in III-Nitride Compound”; U.S. Pat. No. 9,543,168 to Feigelson et al., “Defects Annealing and Impurities Activation in Semiconductors at Thermodynamically Non-Stable Conditions”; and U.S. Pat. No. 10,854,457 to Feigelson et al., “Implanted Dopant Activation for Wide Bandgap Semiconductor Electronics.” In addition to moving the implanted ions to their desired sites within the material, annealing at such high pressures allows for activation of the implanted dopants so that they can be used in electronic devices. In the context, activation indicates physical movement of the dopant atoms onto lattice positions while not being associated with defects (vacancies or interstitial atoms) or other species (impurities, e.g. carbon or hydrogen) such that they may produce free carriers when thermally ionized.

However, as noted above, the GaN surface is exposed to hydrogen from the ambient atmosphere during annealing, potentially causing significant dopant diffusion or association with the dopant species passivating it and precluding generation of free carriers, and consequently, having methods for annealing GaN in the absence of hydrogen is very desirable.

The block schematics in FIGS. 8A-8D illustrate aspects of two exemplary approaches for annealing a GaN sample without exposure to hydrogen from the ambient.

The block schematic in FIG. 8A illustrates aspects of one embodiment of a method for annealing an ion-implanted GaN sample in the absence of hydrogen. As illustrated in FIG. 8A, a hydrogen getter which can withstand the high temperatures needed to anneal GaN such as the Ti/Pt/Pd or Ti/Cr/Pt/Pd getters described above, can be introduced into the anneal chamber along with the material being annealed. In either case, the getter then must retain the hydrogen for the duration of the activation process.

In some embodiments, such as that illustrated in FIG. 8A, the getter can take the form of a thin film 801 directly adhered to a surface of the GaN material 803 to be annealed, while in other embodiments, the getter can be the form of discrete blocks, sheets, or powder of the getter material that are contained within an enclosure situated separately from the GaN material but still within the annealing chamber. In such cases, the getter can be in the form of layered blocks or sheets of material that can withstand the high annealing temperatures, e.g., have the Ti/Pt/Pd or Ti/Cr/Pt/Pd layered structure described above, or can be in the form of Ti/Pt/Pd or Ti/Cr/Pt/Pd core/shell powders situated within a crucible.

It may typically be beneficial for the getter to be in close proximity to the material being activated; however, if the getter has sufficient retention capacity, it may be placed elsewhere during the anneal. An example of this may be inclusion of getter in an adjacent volume which is exposed to the anneal ambient but at a reduced temperature. In any case, the getter must retain the hydrogen for the duration of the activation process.

An alternative embodiment of a method for annealing without exposing the ion implanted GaN to hydrogen from the anneal ambient is illustrated by the block schematic shown in FIG. 8B. In this embodiment, the materials are arranged in a crucible 807 such that the bulk hydrogen getter material 801 is in close proximity but a separate material from the bulk implanted GaN material 805. Such an embodiment can include the deposition, by MBE, MOCVD, sputtering, PLD, or any suitable method, of an n-type, low-doped, or semi-insulating GaN layer 804 on the surface of the ion-implanted bGaN layer 805 after ion implantation but before annealing, as illustrated by the block schematic in FIG. 8B. Such a layer can subsequently be used in device structures or can removed by any suitable means before device fabrication, e.g., by wet etching, dry etching, electrochemical etching, chemical-mechanical polishing.

In addition, due to the challenges in producing high-temperature getters capable of surviving such high-temperature processing conditions, a hydrogen-impermeable barrier layer may be introduced in addition or conjunction or in lieu to the use of a getter material. Such a hydrogen-impermeable barrier must be intimately associated with the material being processed, be compatible with material, and be capable of providing a barrier to hydrogen at high temperatures.

Thus, in an alternative embodiment of a method for annealing without exposing the ion-implanted GaN to hydrogen in the annealing ambient, such as is shown by the block schematic in FIG. 8C, a protective cap which is impermeable to hydrogen, such as hydrogen-blocking cap layer 810 can be deposited on an upper surface of the GaN material, where the GaN material can include an n-type bulk drift layer 812 situated on a substrate 813 with an implanted area of p-type material 811 within the drift layer. This hydrogen-blocking cap layer 810 can be any suitable material, and typically will be an n-type nitride material such as n-type GaN, AlN, InN, ScN, BN, and/or alloys thereof. This hydrogen-blocking cap layer can be deposited by any suitable means including physical vapor deposition (sputtering, evaporation, pulsed laser deposition, etc.), chemical vapor deposition, atomic layer deposition, etc. This cap then blocks permeation of hydrogen into the GaN, precluding exposure of the GaN to the hydrogen.

Further protection of the ion-implanted material from exposure to hydrogen can optionally be done by implanting the magnesium (or other p-type dopant) with a buried or retrograde structure, such as the buried p-type GaN material 811 shown in FIG. 8C. Burying the ion-implanted GaN 805 below unimplanted GaN material 804 results in the majority of the implanted magnesium being beneath the GaN surface, with a low or negligible concentration of magnesium at the surface exposed to the annealing ambient. with. Due to the significant difference in diffusion of hydrogen between n-type and p-type GaN, where diffusion is significantly slower in n-type GaN, surface GaN film 804 can protect the buried magnesium implanted material from any hydrogen remaining in the anneal ambient if the top surface n-type, intrinsic, or devoid of acceptors.

In another alternative embodiment of a method for annealing without exposing the ion-implanted GaN to hydrogen from the anneal ambient, shown in FIG. 8D, an in-situ hydrogen-blocking layer which is impermeable to hydrogen, such as an n-type ion-implanted layer 820 is introduced to globally or selectively block hydrogen diffusion into the p-type regions 821 within the drift layer 822. This n-type region then blocks permeation of hydrogen into the p-type GaN layer precluding exposure of this region to hydrogen. Such an n-type GaN layer can be created in-situ by implanting donors like silicon, oxygen, germanium, tin, etc., at a more shallow depth than the magnesium to provide the hydrogen-impermeable layer. This could be done across the entire material surface, or selectively to produce areas with minimal diffusion on the same substrate as with areas that are intentionally allowed to diffuse deeply in support of the desired device structure.

After annealing the sample to activate the magnesium, the p-type layer can be accessed either by a local recess etch or global etch to remove the n-type GaN layer.

Irrespective of the arrangement of the getter or hydrogen-blocking layer, the anneal of the ion-implanted GaN can then proceed, with the pressure and temperature being increased to those sufficient to activate the ion-implanted dopants and/or remove ion implanted damage, e.g., pressures of about 10-2000 MPa and temperatures of 1200-1500° C. in the case of GaN, with an annealing duration of minutes to hours. Such anneals may be performed in a Hot Isostatic Press (HIP) or any similar equipment capable of reaching the relevant temperatures and pressures.

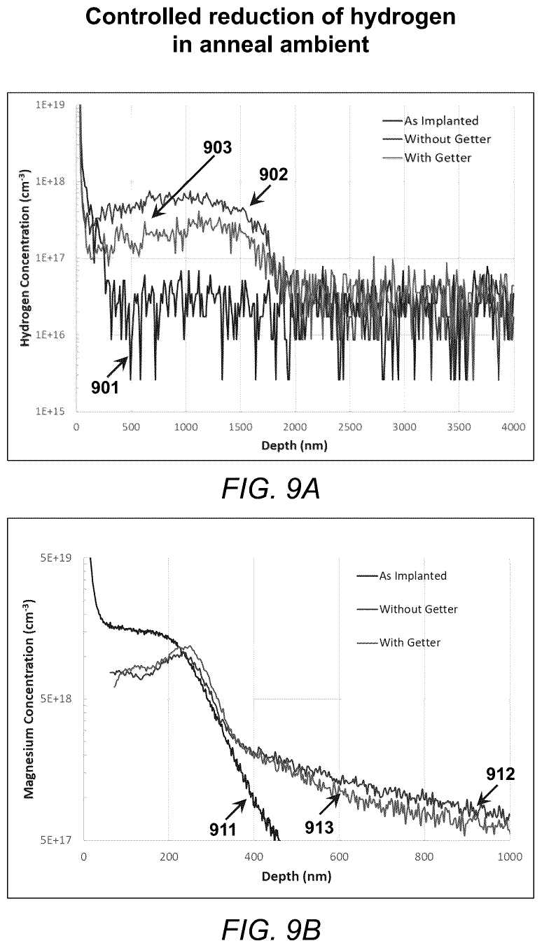

FIGS. 9A and 9B are plots illustrating the effects of including a hydrogen getter in accordance with this invention during an anneal of GaN at 1300° C. for 30 minutes. FIG. 9A shows the hydrogen concentration in samples as implanted with magnesium (plotline 901), no hydrogen is inside the GaN. After annealing without a getter (plotline 902), the hydrogen diffuses into the GaN, while after annealing with the getter (plotline 903), the hydrogen concentration is reduced. FIG. 9B shows the magnesium concentration in the same region, where plotlines 911, 912, and 913 show a reduction in the magnesium diffusion into the GaN by ˜35% at 1 micron in depth with the use of the hydrogen getter.

### Advantages and New Features

The present invention allows activation of ion implanted dopants in nitrides, with the exemplary case of magnesium in gallium nitride, without the presence of hydrogen.

This provides several benefits.

First, the magnesium (or dopant) has suppressed diffusion due to the removal of hydrogen from the anneal ambient meaning that the as-implanted dopant profile can be maintained after annealing and activation. This is important for electronic device design and especially for maintaining high doping concentrations needed in some device architectures and especially for low resistance ohmic contacts.

Second, the magnesium (or dopant) can be passivated by the hydrogen such that it does not produce electrically active carriers despite occupying the correct lattice position away from other defects. Often, a de-hydrogenation process must be completed after activation to enable device operation. Precluding hydrogen incorporation during activation removes or reduces the necessity of a de-hydrogenation process simplifying device fabrication.

Furthermore, the presence of hydrogen within the nitride material may have implications for device long-term stability and longevity meaning a reduction in hydrogen may produce a more stable device.

Although particular embodiments, aspects, and features have been described and illustrated, one skilled in the art would readily appreciate that the invention described herein is not limited to only those embodiments, aspects, and features but also contemplates any and all modifications and alternative embodiments that are within the spirit and scope of the underlying invention described and claimed herein. The present application contemplates any and all modifications within the spirit and scope of the underlying invention described and claimed herein, and all such modifications and alternative embodiments are deemed to be within the scope and spirit of the present disclosure.

What is claimed is:

1. A method for preventing penetration of hydrogen from an ambient into a material sample during high-temperature processing, comprising:
placing a material sample to be treated into an processing chamber;
placing a high-temperature hydrogen getter into the annealing chamber adjacent to the material sample being processed; and
processing the material sample at a temperature of about 500 to about 2000° C. and at a pressure of about 0.1 to about 2000 MPa;
wherein the high-temperature hydrogen getter absorbs hydrogen from the processing ambient and prevents the hydrogen from penetrating into the material sample during processing at the processing temperature.

2. The method according to claim 1, wherein the high-temperature hydrogen getter comprises:
a getter material that absorbs and retains hydrogen from the processing ambient;
a surface material that protects the getter material from damage from elements in the annealing ambient at the processing temperature; and
a diffusion-blocking layer situated between the getter material and the surface material, the diffusion-blocking layer preventing diffusion between the getter material and the surface material at the processing temperature.

3. The method according to claim 1, wherein the material sample is a III-Nitride material.

4. The method according to claim 1, wherein the material sample is an III-Nitride sample implanted with dopant ions;
wherein the high-temperature processing is an annealing to activate the implanted dopant ions; and
wherein the hydrogen getter absorbs hydrogen from the processing ambient at an annealing temperature.

5. The method according to claim 4, wherein the III-Nitride material sample is GaN; and
wherein the annealing temperature is about 800 to about 1500° C.

6. A method for preventing penetration of hydrogen from an ambient into a material sample during high-temperature processing, comprising:
placing a material sample to be treated into an processing chamber;
placing a high-temperature hydrogen-blocking barrier layer into the annealing chamber adjacent to the material sample being processed; and
processing the material sample at a temperature of about 500 to about 2000° C. and at a pressure of about 0.1 to about 2000 MPa;
wherein a high-temperature hydrogen-blocking layer prevents hydrogen from the processing ambient from penetrating into the material sample during processing at the processing temperature.

7. The method according to claim 6, wherein the high-temperature hydrogen-blocking layer comprises n-type GaN, AlN, InN, ScN, BN, and/or alloys thereof.

8. The method according to claim 6, wherein the high-temperature hydrogen-blocking layer comprises a layer deposited on an upper surface of the material sample before processing.

9. The method according to claim 6, wherein the high-temperature hydrogen-blocking layer comprises an separate material layer situated within the material sample being processed.

10. The method according to claim 6, wherein the high-temperature hydrogen-blocking layer comprises an in-situ dopant-implanted region within the material sample being processed.

11. The method according to claim 6, wherein the material sample is p-type and the high-temperature hydrogen-blocking layer is n-type.

12. The method according to claim 6, wherein the material sample is an III-Nitride sample implanted with dopant ions;
wherein the high-temperature processing is an annealing to activate the implanted dopant ions; and
wherein the hydrogen-blocking layer prevents hydrogen from the annealing ambient from penetrating into the III-Nitride sample at an annealing temperature.

13. The method according to claim 12, wherein the III-Nitride material sample is GaN; and
wherein the annealing temperature is about 800 to about 1500° C.

14. The method according to claim 6, wherein the material sample comprises a III-Nitride material and the high-temperature hydrogen-blocking layer is a doped layer of the III-Nitride material.

15. The method according to claim 6, wherein the material sample comprises a p-type III-Nitride material- and the high-temperature hydrogen-blocking layer comprises an n-type material layer deposited on the p-type III-Nitride material layer.

16. The method according to claim 6, wherein the material sample comprises a p-type III-Nitride material situated within an n-type drift layer and the high-temperature hydrogen-blocking layer comprises an in-situ doped area of the n-type drift layer.
